(19) United States
(12) Patent Application Publication
(10) Pub. No.: US 2026/0258281 A1
(43) Pub. Date: Sep. 3, 2026

(54) POLISHING SLURRY COMPOSITION FOR SILICON CARBIDE WAFER

(71) Applicant: IUCF-HYU (INDUSTRY-UNIVERSITY COOPERATION FOUNDATION HANYANG UNIVERSITY ), Seoul (KR)

(72) Inventors: Bo Hyeok CHOI, Hwaseong-si, Gyeonggi-do (KR); Eu Ock KIM, Pyeongtaek-si, Gyeonggi-do (KR); Na Ra SHIN, Anseong-si, Gyeonggi-do (KR); Suyeong JUNG, Hwaseong-si, Gyeonggi-do (KR); Dongwook KIM, Suwon-si, Gyeonggi-do (KR); Ungyu PAIK, Seoul (KR); Taeseup SONG, Seoul (KR); Ganggyu LEE, Seoul (KR)

(73) Assignee: IUCF-HYU (INDUSTRY-UNIVERSITY COOPERATION FOUNDATION HANYANG UNIVERSITY ), Seoul (KR)

(21) Appl. No.: 18/875,379

(22) PCT Filed: May 30, 2023
(86) PCT No.: PCT/KR2023/007368

§ 371 Date: Mar. 4, 2025

(30) Foreign Application Priority Data
Jun. 17, 2022 (KR) 10-2022-0074361
May 23, 2023 (KR) 10-2023-0066590

(51) Int. Cl. C09G 1/02; C09K 3/14; H10P 52/40

(52) U.S. Cl. CPC C09G 1/02; C09K 3/1409; H10P 52/407

(57) ABSTRACT

The present invention relates to a polishing slurry composition for a silicon carbide wafer, and a polishing slurry composition for a silicon carbide wafer according to an embodiment of the present invention comprises polishing particles, an oxidant, a water-soluble transition metal, and a transition metal ion complexing agent.

### TECHNICAL FIELD

The disclosure relates to a polishing slurry composition for a silicon carbide wafer.

### BACKGROUND ART

A polishing slurry for a silicon carbide (SiC) wafer has included polishing particles with a high hardness such as alumina particles, diamond particles, or SiC particles for a high polishing speed.

The polishing particles with a hardness higher than that of SiC provide a high polishing speed, however, cause significant surface and subsurface damage. On the other hand, polishing particles that are softer than silicon carbide provide less damage, but have a very slow polishing speed, thereby requiring long chemical mechanical polishing (CMP) process time. It is necessary to provide a polishing slurry that achieves a high polishing speed for improvement of productivity while using polishing particles with a hardness lower than that of SiC for less damage on the surface.

SiC has unique physical and electrical properties that make it suitable for high-power, high-frequency, and high-temperature electronic devices. To manufacture SiC electronic devices, flat SiC wafers need to be prepared. The preparation of SiC wafers involves a CMP process to flatten the surface.

In a SiC CMP slurry of the related art, particles harder than SiC (Mohs hardness of 9, Knoop hardness of 2,400 to 3,000 Kg/mm), such as diamond (Mohs hardness of 10, Knoop hardness of 8,000 to 12,000 Kg/mm), are used to achieve a high SiC polishing speed.

However, the particles with a hardness higher than that of SiC cause a high degree of damage to a surface of the SiC, including scratches and dislocations that are typically generated on a surface and sub-surface of the wafer. To reduce the surface damage, there have been attempts to perform the CMP using particles with a low hardness, such as titania (Mohs hardness of 5.5 to 6.5, Knoop hardness of 500 to 600 Kg/mm), garnet (Mohs hardness of about 8, Knoop hardness of 1,360 Kg/mm), silica/quartz (Mohs hardness of 7, Knoop hardness of 900 to 1,200 Kg/mm), or zirconia (Mohs hardness of about 8, Knoop hardness of 1,120 Kg/mm). However, the polishing particles softer than SiC provide less damage, but have a very slow polishing speed, thereby requiring long CMP process time.

Accordingly, it is necessary to provide a chemically activated slurry that may increase the polishing speed while using particles with a hardness lower than that of SiC.

The above description has been possessed or acquired by the inventor(s) in the course of conceiving the present disclosure and is not necessarily an art publicly known before the present application is filed.

### DISCLOSURE OF THE INVENTION

### Technical Goals

The disclosure has been made in view of the aforementioned problems and an object thereof is to provide a polishing slurry composition for a silicon carbide wafer that may implement a high polishing speed with less surface damage.

However, technical goals to be achieved are not limited to those described above, and other goals not mentioned above may be clearly understood by one of ordinary skill in the art from the following description.

### Technical Solutions

A polishing slurry composition for a silicon carbide wafer according to an embodiment of the present disclosure includes polishing particles; an oxidant; a water-soluble transition metal; and a transition metal ion complexing agent.

In an embodiment, the polishing particles may have a Mohs hardness lower than a Mohs hardness of silicon carbide.

In an embodiment, the polishing particles may include at least one selected from the group consisting of metal oxide, metal oxide coated with an organic or inorganic substance, and the metal oxide in a colloidal state, and the metal oxide may include at least one selected from the group consisting of silica, ceria, zirconia, alumina, titania, barium titania, germania, mangania, and magnesia.

In an embodiment, the polishing particles may include primary particles having a particle size of 30 nanometers (nm) to 100 nm and secondary particles having a particle size of 250 nm to 300 nm.

In an embodiment, the polishing particles may be in an amount of 0.1 wt % to 10 wt % in the polishing slurry composition for the silicon carbide wafer.

In an embodiment, the oxidant may include at least one selected from the group consisting of potassium permanganate (KMnO₄), potassium ferricyanide, potassium dichromate, potassium iodate, potassium bromate, potassium hypochlorite, sodium permanganate (NaMnO₄), sodium hypochlorite (NaClO), sodium bromate (NaBrO₃), hydrogen peroxide, ammonium persulfate, silver nitrate, ferric nitrates, ferric chloride, per acid, per salts, ozone water, vanadium trioxide, hypochlorous acid, sodium hypochlorite, calcium hypochlorite, magnesium hypochlorite, and ferric nitrate.

In an embodiment, the oxidant may be included in an amount of 0.1 M to 5 M in the polishing slurry composition for the silicon carbide wafer.

In an embodiment, the water-soluble transition metal may include chromium (Cr) ions, iron (Fe) ions, or both.

In an embodiment, the chromium (Cr) ions may be provided from an iron compound including at least one selected from the group consisting of chromium (III) sulfate, chromium (III) chloride, chromium (III) nitrate, and chromium (III) acetate.

In an embodiment, the iron (Fe) ions may be provided from an iron compound including at least one selected from the group consisting of iron (III) nitrate, iron (III) sulfate, iron (III) formate, iron (III) acetate, iron (III) carbonate, iron (III) chloride, iron (III) bromide, iron (III) oxalate, iron (III) hydroxide, iron (III) oxide, iron (III) acetylacetone, iron (III) carbon monoxide, iron (III) citrate, iron (III) oxalate, iron (III) fumarate, iron (III) lactate, iron (III) perchlorate, ammonium hexacyanoferrate (III) acid, potassium hexacyanoferrate (III) acid, ammonium iron (III) sulfate, and potassium iron (III) sulfate.

In an embodiment, the water-soluble transition metal may be included in an amount of 0.0001 M to 0.1 M in the polishing slurry composition for the silicon carbide wafer.

In an embodiment, the transition metal ion complexing agent may include ions of at least one selected from the group consisting of NO₂⁻, CN⁻, and C₅H₇O₂⁻ (acetylacetonate).

In an embodiment, the transition metal ion complexing agent may include at least one selected from the group consisting of NaNO₂, NaCN, NaAcc, KNO₂, KCN, and HNO₂.

In an embodiment, a molar ratio of the water-soluble transition metal to the transition metal ion complexing agent may be 1:0.5 to 1:5.

In an embodiment, the polishing slurry composition for a silicon carbide wafer may further include a surfactant.

In an embodiment, the polishing slurry composition may further include a surfactant, and the surfactant may include at least one selected from the group consisting of dodecylbenzenesulfonic acid, octylbenzenesulfonic acid, decylbenzenesulfonic acid, dodecanesulfonic acid, tetradecylbenzenesulfonic acid, alkylbenzenesulfonic acid, alkyldiphenyletherdisulfonic acid, polystyrenesulfonate, polysodium styrenesulfonate, sodium dodecylsulfonate, dodecylbenzenesulfonate, n-dodecylpyridinium chloride, linear diamine, linear alkylamine, cetyltrimethylammonium bromide, benzalkonium chloride, benzethonium chloride, cetrimonium chloride, alkyltrimethylammonium chloride, dialkyldimethylammonium chloride, imidazole, glyceride sulfate, dodecylbenzene sulfonate, sodium dodecyl sulfonate, ligrosulfonate, sarcoside, a sulfo-carboxyl compound, alkyl ether sulfate, alkyl sulfate, alpha-olefin sulfonate, an organophosphate-based surfactant, potassium cocoyl glycinate, sulfate alkanolamide, Brij 35, Brij 58, Brij L23, Brij O20, sorbitan monolaurate, sorbitan monostearate, sorbitan tristearate, octaethylene glycol monododecyl ether, pentaethylene glycol monododecyl ether, nonoxynols, Triton X-100, Tween 80, sodium dodecyl sulfate (SDS), sodium deoxycholate, and Triton X-200.

In an embodiment, the surfactant may be included in an amount of 0.2 mM to 5 mM in the polishing slurry composition for the silicon carbide wafer.

In an embodiment, the polishing slurry composition for the silicon carbide wafer may have a pH of 2 to 5.

In an embodiment, when polishing a silicon carbide wafer using the polishing slurry composition for the silicon carbide wafer, a removal rate of a silicon carbide film is 400 nm/h to 1,000 nm/h.

In an embodiment, when polishing a silicon carbide wafer using the polishing slurry composition for the silicon carbide wafer, a silicon oxide film (SiO₂) may be formed on the silicon carbide surface by the oxidant, and the polishing particles may polish the silicon oxide film (SiO₂).

### Effects of the Invention

A polishing slurry composition for a silicon carbide wafer according to an embodiment of the present disclosure may include water-soluble transition metal ions and a transition metal ion complexing agent capable of undergoing an oxidation-reduction reaction with a reduced form of an oxidant to increase a surface oxidation reaction speed, thereby increasing a formation speed of a silicon oxide film (SiO₂). Through this, a high polishing speed may be secured even when polishing particles with a low hardness are used.

### BRIEF DESCRIPTION OF DRAWINGS

FIG. 1 is a graph showing corrosion currents and removal rates after performing polishing using polishing slurry compositions of Comparative Examples 1 to 3 of the present disclosure and polishing slurry compositions for a silicon carbide wafer of Examples 1 to 3.

FIG. 2 is an image for confirming whether silica particle surface is coated according to iron (III) acetylacetonate, iron (III) nitrate, and chromium (III) nitrate as transition metal ions.

FIG. 3 is a graph showing corrosion currents and removal rates after performing polishing using polishing slurry compositions of Comparative Examples 1 and 2 of the present disclosure and polishing slurry compositions for a silicon carbide wafer of Examples 2, 4, and 5.

### BEST MODE FOR CARRYING OUT THE INVENTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but 30 do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, terms such as first, second, A, B, (a), (b), and the like may be used to describe components of the embodiments. These terms are used only for the purpose of discriminating one component from another component, and the nature, the sequences, or the orders of the components are not limited by the terms.

The same name may be used to describe an element included in the embodiments described above and an element having a common function. Unless otherwise mentioned, the descriptions on the embodiments may be applicable to the following embodiments and thus, duplicated descriptions will be omitted for conciseness.

The disclosure relates to research and development of chemical mechanical polishing (CMP) slurry for application to next-generation devices with the support of KC Tech.

Hereinafter, a polishing slurry composition for a silicon carbide wafer according to the present disclosure will be described in detail with reference to embodiments and drawings. However, the present disclosure is not limited to the embodiments and drawings.

A polishing slurry composition for a silicon carbide wafer according to an embodiment of the disclosure includes polishing particles; an oxidant; a water-soluble transition metal; and a transition metal ion complexing agent.

In an embodiment, the polishing particles may have a Mohs hardness lower than a Mohs hardness of silicon carbide.

The polishing particles may be, for example, silica (SiO₂) nanoparticles. It is very difficult to mechanically polish single crystal silicon carbide (SiC) with a Mohs hardness of 9.5 using silica nanoparticles with a low hardness. Therefore, the CMP is performed by not directly polishing silicon carbide (SiC) using polishing particles, but by oxidizing a surface of silicon carbide (SiC) to generate a silicon oxide film (SiO₂), and then polishing the relatively soft silicon oxide film (SiO₂) using polishing particles. In a chemically activated polishing slurry composition using silica particles with a low hardness, a polishing speed may also increase as an oxidation reaction rate of the silicon carbide (SiC) surface increases.

In an embodiment, the polishing particles may include at least one selected from the group consisting of metal oxide, metal oxide coated with an organic or inorganic substance, and the metal oxide in a colloidal state, and the metal oxide may include at least one selected from the group consisting of silica, ceria, zirconia, alumina, titania, barium titania, germania, mangania, and magnesia.

In an embodiment, the polishing particles may be manufactured by a liquid method.

Desirably, the polishing particles may be colloidal silica.

In an embodiment, the polishing particles may include those manufactured by a liquid method. The liquid method may be used to manufacture polishing particles by applying a sol-gel method, which causes a chemical reaction in an aqueous solution with a polishing particle precursor and grows crystals to obtain fine particles, a coprecipitation method, which precipitates polishing particle ions in an aqueous solution, and a hydrothermal synthesis method, which forms polishing particles at a high temperature under high pressure. The polishing particles manufactured by the liquid method are dispersed so that the surfaces of the polishing particles have a positive charge.

In an embodiment, the polishing particles may be monocrystalline. When monocrystalline polishing particles are used, a scratch reduction effect may be achieved compared to polycrystalline polishing particles, dishing may be improved, and a cleaning property after polishing may be improved.

In an embodiment, a shape of the abrasive particle may include at least one selected from the group consisting of a spherical shape, a square shape, a needle shape, and a plate shape, and may be desirably a spherical shape.

In an embodiment, the polishing particles may include primary particles having a particle size of 30 nm to 100 nm; 50 nm to 100 nm; 80 nm to 100 nm; 90 nm to 100 nm; 30 nm to 90 nm; 50 nm to 90 nm; 70 nm to 90 nm; 80 nm to 90 nm; or 70 nm to 80 nm, and secondary particles having a particle size of 250 nm to 300 nm; 280 nm to 300 nm; 250 nm to 280 nm; 260 nm to 280 nm; or 250 nm to 260 nm.

For example, an average particle size of the polishing particles is an average value of particle sizes of a plurality of articles within the field of view that may be measured by scanning electron microscopy analysis or dynamic light scattering.

In an embodiment, the size of the primary particles is required to be 70 nm or less to secure particle uniformity, and when the size thereof is less than 70 nm, the removal rate may be reduced. Regarding the size of the secondary particles in the polishing slurry composition for a silicon carbide wafer for the STI process, when the size of the secondary particles is less than 100 nm, cleanability may be reduced and excessive defects may occur on a wafer surface if an excessively large amount of small particles are generated due to milling, and when the size thereof exceeds 300 nm, excessive polishing may occur, making it difficult to control selectivity, and there is a possibility that dishing, erosion, and surface defects may occur.

According to an aspect, the polishing particles may use mixed particles including a particle distribution in a multi-dispersion form, in addition to single-size particles. For example, polishing particles having two different average particle sizes may be mixed to have a bimodal particle distribution, or polishing particles having three different average particle sizes may be mixed to have a particle size distribution showing three peaks. Alternatively, polishing particles having four or more different average particle sizes may be mixed to have a multi-dispersion particle distribution. Relatively large and relatively small polishing particles are mixed to obtain more excellent dispersion and expect an effect of reducing scratches on the wafer surface.

In an embodiment, the polishing particles may be in an amount of 0.1 wt % to 10 wt %; 0.5 wt % to 10 wt %; 0.5 wt % to 10 wt %; 0.5 wt % to 10 wt %; 1 wt % to 10 wt %; 3 wt % to 10 wt %; 5 wt % to 10 wt %; or 7 wt % to 10 wt % in the polishing slurry composition for a silicon carbide wafer. When the polishing particles are in an amount of less than 0.1 wt % in the polishing slurry composition for the silicon carbide wafer, the polishing speed may be reduced, and when the polishing particles are in an amount of more than 10 wt %, there may be a problem that defects occur due to the polishing particles.

Desirably, the polishing particles may be in an amount of 3 wt % to 7 wt %; or 4 wt % to 6 wt % in the polishing slurry composition for the silicon carbide wafer.

In an embodiment, the oxidant may include at least one selected from the group consisting of potassium permanganate (KMnO₄), potassium ferricyanide, potassium dichromate, potassium iodate, potassium bromate, potassium hypochlorite, sodium permanganate (NaMnO₄), sodium hypochlorite (NaClO), sodium bromate (NaBrO₃), hydrogen peroxide, ammonium persulfate, silver nitrate, ferric nitrates, ferric chloride, per acid, per salts, ozone water, vanadium trioxide, hypochlorous acid, sodium hypochlorite, calcium hypochlorite, magnesium hypochlorite, and ferric nitrate.

Desirably, the oxidant may be potassium permanganate (KMnO₄). For example, the MnO₄⁻ ions of potassium permanganate reacts with silicon carbide (SiC) to oxidize the wafer while being reduced into a form of MnO₄²⁻ or MnO₂. To further promote the reaction, transition metal ions are included, which reoxidizes the reduced MnO₄²⁻— or MnO₂ to regenerate it into a form of MnO₄⁻ which may react with the silicon carbide (SiC). Due to this regeneration reaction, an oxidant capable of reacting with the silicon carbide (SiC) may be re-formed, and at the same time, the formation of undissolved MnO₂, which is adsorbed on the surface of silicon carbide (SiC) and blocks the reaction site, may be suppressed, thereby further promoting the oxidation reaction on the surface of silicon carbide (SiC).

In an embodiment, the oxidant may be included in an amount of 0.1 M to 5 M in the polishing slurry composition for the silicon carbide wafer. When the oxidant is included in an amount of less than 0.1 M in the polishing slurry composition for the silicon carbide wafer, the formation of a silicon oxide film (SiO₂) on a surface of a silicon carbide film may be minimal, and when the oxidant is included in an amount of more than 5 M, the film surface may be excessively etched, which may cause a problem of increased roughness.

In an embodiment, the water-soluble transition metal may include chromium (Cr) ions, iron (Fe) ions, or both.

In an embodiment, the chromium (Cr) ions may be provided from an iron compound including at least one selected from the group consisting of chromium (III) sulfate, chromium (III) chloride, chromium (III) nitrate, and chromium (III) acetate.

In an embodiment, the iron (Fe) ions may be provided from an iron compound including at least one selected from the group consisting of iron (III) nitrate, iron (III) sulfate, iron (III) formate, iron (III) acetate, iron (III) carbonate, iron (III) chloride, iron (III) bromide, iron (III) oxalate, iron (III) hydroxide, iron (III) oxide, iron (III) acetylacetone, iron (III) carbon monoxide, iron (III) citrate, iron (III) oxalate, iron (III) fumarate, iron (III) lactate, iron (III) perchlorate, ammonium hexacyanoferrate (III) acid, potassium hexacyanoferrate (III) acid, ammonium iron (III) sulfate, and potassium iron (III) sulfate.

For example, iron(III) nitrate (Fe(NO₃)₃) dissociates in water to provide iron ions (Fe³⁺).

In an embodiment, the water-soluble transition metal may be included in an amount of 0.0001 M to 0.1 M in the polishing slurry composition for the silicon carbide wafer. When the water-soluble transition metal is included in an amount of less than 0.0001 M in the polishing particles, a synergistic effect of polishing and silicon carbide film oxidation may not be sufficiently obtained, and when the water-soluble transition metal is included in an amount of more than 0.1 M, iron or chromium atoms are used, which only causes difficulty in controlling the polishing speed.

The transition metal ion complexing agent may be included because it may further promote the oxidant regeneration reaction of the transition metal ions by a ligand of the transition metal ions.

In an embodiment, the transition metal ion complexing agent may include ions of at least one selected from the group consisting of NO₂⁻, CN⁻, and C₅H₇O₂⁻ (acetylacetonate).

For example, when the transition metal ion complexing agent, such as NO₂⁻, CN⁻, and C₅H₇O₂⁻, is included, the oxidant regeneration reaction of the transition metal ions may be further promoted, thereby further increasing the polishing speed.

In an embodiment, the transition metal ion complexing agent may include at least one selected from the group consisting of NaNO₂, NaCN, NaAcc, KNO₂, KCN, and HNO₂.

In an embodiment, a molar ratio of the water-soluble transition metal to the transition metal ion complexing agent may be 1:0.5 to 1:5; 1:0.5 to 1:3; or 1:1 to 1:1.5.

Desirably, the molar ratio of the water-soluble transition metal to the transition metal ion complexing agent may be 1:1. If more than that is added, the transition metal ion complexing agent precipitates and forms a soft layer on the polishing particles, which reduces the polishing speed.

In an embodiment, the polishing slurry composition for a silicon carbide wafer may further include a surfactant.

In an embodiment, the surfactant may be added to reduce defects on the surface of a silicon carbide wafer after polishing.

In an embodiment, the surfactant may include at least one selected from the group consisting of dodecylbenzenesulfonic acid, octylbenzenesulfonic acid, decylbenzenesulfonic acid, dodecanesulfonic acid, tetradecylbenzenesulfonic acid, alkylbenzenesulfonic acid, alkyldiphenyletherdisulfonic acid, polystyrenesulfonate, polysodium styrenesulfonate, sodium dodecylsulfonate, dodecylbenzenesulfonate, n-dodecylpyridinium chloride, linear diamine, linear alkylamine, cetyltrimethylammonium bromide, benzalkonium chloride, benzethonium chloride, cetrimonium chloride, alkyltrimethylammonium chloride, dialkyldimethylammonium chloride, imidazole, glyceride sulfate, dodecylbenzene sulfonate, sodium dodecyl sulfonate, ligrosulfonate, sarcoside, a sulfo-carboxyl compound, alkyl ether sulfate, alkyl sulfate, alpha-olefin sulfonate, an organophosphate-based surfactant, potassium cocoyl glycinate, sulfate alkanolamide, Brij 35, Brij 58, Brij L23, Brij O20, sorbitan monolaurate, sorbitan monostearate, sorbitan tristearate, octaethylene glycol monododecyl ether, pentaethylene glycol monododecyl ether, nonoxynols, Triton X-100, Tween 80, sodium dodecyl sulfate (SDS), sodium deoxycholate, and Triton X-200.

In an embodiment, the surfactant may be included in an amount of 0.2 mM to 5 Mm; 0.5 mM to 5 Mm; 1 mM to 5 Mm; 3 mM to 5 Mm; 0.2 mM to 3 Mm; 0.5 mM to 3 Mm; 1 mM to 3 Mm; 0.2 mM to 1 Mm; or 0.5 mM to 1 Mm in the polishing slurry composition for the silicon carbide wafer. When the surfactant is included in an amount of less than 0.2 mM in the polishing slurry composition for the silicon carbide wafer, the ability to remove defects on the surface of the silicon carbide wafer may not be exhibited, and even when the surfactant is included in an amount of more than 5 mM, no further effect is obtained, and therefore, it is not desirable from an economical perspective.

In an embodiment, the polishing slurry composition for the silicon carbide wafer may have a pH of 2 to 5. For example, the pH of the polishing slurry composition for the silicon carbide wafer may be 2 to 4, 2 to 3, or 3 to 5.

The polishing slurry composition for the silicon carbide wafer according to an embodiment of the present disclosure may further include a pH adjuster.

In an embodiment, the pH adjuster may include at least one selected from the group consisting of an acidic substance including at least one selected from the group consisting of nitric acid, hydrochloric acid, phosphoric acid, sulfuric acid, hydrofluoric acid, bromic acid, iodic acid, formic acid, malonic acid, maleic acid, oxalic acid, acetic acid, adipic acid, citric acid, adipic acid, acetic acid, propionic acid, fumaric acid, lactic acid, salicylic acid, pimelic acid, benzoic acid, succinic acid, phthalic acid, butyric acid, glutaric acid, glutamic acid, glycolic acid, lactic acid, aspartic acid, tartaric acid and salts thereof; and an alkaline substance including at least one selected from the group consisting of ammonia, 2-amino-2-methyl-1-propanol, tetramethylammonium hydroxide, potassium hydroxide, sodium hydroxide, magnesium hydroxide, rubidium hydroxide, cesium hydroxide, sodium bicarbonate, sodium carbonate, and imidazole.

In an embodiment, a manufacturing process for the polishing slurry composition for the silicon carbide wafer may include a concentration process and a dilution process.

In an embodiment, the polishing slurry composition for the silicon carbide wafer may further include water, and a ratio of the polishing solution: water:additive solution may be 1:3 to 10:1 to 8. The water may include, for example, deionized water, ion exchange water, and ultrapure water.

In an embodiment, the polishing solution and the additive solution may be prepared separately to be provided in a two-component form to be used by being mixed immediately before polishing, or the polishing solution and the additive solution may be provided in a one-component form in which the polishing solution and the additive solution are mixed.

In an embodiment, when polishing a silicon carbide wafer using the polishing slurry composition for the silicon carbide wafer, the removal rate of the silicon carbide film may be 400 nm/h to 1,000 nm/h.

In an embodiment, when polishing a silicon carbide wafer using the polishing slurry composition for the silicon carbide wafer, a silicon oxide film (SiO₂) may be formed on the surface of the silicon carbide by the oxidant, and the polishing particles may polish the silicon oxide film (SiO₂).

The polishing slurry composition for the silicon carbide wafer according to an embodiment of the present disclosure may include the water-soluble transition metal ions and the transition metal ion complexing agent capable of undergoing an oxidation-reduction reaction with a reduced form of an oxidant to increase a surface oxidation reaction speed, thereby increasing a formation speed of the silicon oxide film (SiO₂). Through this, a high polishing speed may be secured even when polishing particles with a low hardness are used.

Hereinafter, the present disclosure will be described in more detail with reference to examples and comparative examples.

However, However, the following examples are only for illustrating the present disclosure, and the present disclosure is not limited to the following examples.

### EXAMPLES

### Comparative Example 1

A polishing slurry composition was manufactured by adding SC1AJ (Sinmat, Inc.) polishing particles as the polishing particles.

### Comparative Example 2

A polishing slurry composition having a pH of 4.0 was manufactured by adding 5 wt % of 100 nm silica as the polishing particles and 0.3 M of potassium permanganate (KMnO₄) as the oxidant.

### Comparative Example 3

A polishing slurry composition having a pH of 4.0 was manufactured by adding 5 wt % of 100 nm silica as the polishing particles, 0.3 M of potassium permanganate (KMnO₄) as the oxidant, 0.008 M of manganese acetylacetonate (Mn(acc)₃) as the water-soluble transition metal ions, and HNO₃ (nitric acid) as the pH adjuster.

### Comparative Example 4

A polishing slurry composition having a pH of 9.0 was manufactured by adding 5 wt % of 100 nm silica as the polishing particles, 0.3 M of potassium permanganate (KMnO₄) as the oxidant, 0.008 M of manganese acetylacetonate (Mn(acc)₃) as the water-soluble transition metal ions, and KOH (potassium hydroxide) as the pH adjuster.

### Example 1

A polishing slurry composition for a silicon carbide wafer was manufactured by adding 0.008 M of chromium nitrate (Cr(NO₃)₃) as the water-soluble transition metal to the polishing slurry composition of Comparative Example 2.

### Example 2

A polishing slurry composition for a silicon carbide wafer was manufactured by adding 0.008 M of iron nitrate (Fe(NO₃)₃) as the water-soluble transition metal to the polishing slurry composition of Comparative Example 2.

### Example 3

A polishing slurry composition for a silicon carbide wafer was manufactured by adding 0.004 M of chromium nitrate (Cr(NO₃)₃) and 0.004 M of iron nitrate (Fe(NO₃)₃) as the water-soluble transition metal to the polishing slurry composition of Comparative Example 2.

### Example 4

0.008 M of NaNO₂ as the transition metal ion complexing agent was added to the polishing slurry composition for a silicon carbide wafer of Example 2 so that a ratio of Fe³⁺ ions to NaNO₂ was 1:1.

### Example 5

0.08 M of NaNO₂ as the transition metal ion complexing agent was added to the polishing slurry composition for a silicon carbide wafer of Example 2 so that a ratio of Fe³⁺ ions to NaNO₂ was 1:10.

### Example 6

A polishing slurry composition for a silicon carbide wafer having a pH of 2 was manufactured by adding 0.008 M of iron nitrate (Fe(NO₃)₃) as the water-soluble transition metal to the polishing slurry composition of Comparative Example 2.

A SiC wafer was polished using the slurry compositions of Comparative Examples 1 to 4 and the polishing slurry compositions for a silicon carbide wafer of Examples 1 to 6 manufactured as described above under the following polishing conditions.

### [Polishing Conditions]

1. Polisher: JSPM2011-D (JS lab)
2. Pad: T-SCF-39M (Sinmat Inc.)
3. Polishing time: 1 h
4. Platen/Head speed: 25/20 rpm
5. Pressure: 300 gf/cm²
6. Flow rate: 1.5 ml/min
7: Wafer: SiC 4 inch, 4H-N type, 4-degree off orientation

Table 1 below shows results of corrosion currents and removal rates after polishing a SiC wafer using the polishing slurry compositions of Comparative Examples 1 to 4 of the present disclosure and polishing slurry compositions for a silicon carbide wafer of Examples 1 to 6.

### Measurement of Corrosion Current

Flat cell kit (AMETEK scientific instruments)
Counter electrode: Pt
Reference electrode: Ag/AgCl

TABLE 1

| | | | Water- | Transition | | | |
|---|---|---|---|---|---|---|---|
| | | | soluble | metal ion | | Corrosion | Removal |
| | Polishing | | transition | complexing | | current | rate |
| | particles | Oxidant | metal ions | agent | pH | [uA/cm²] | [nm/h] |
| Comparative | — | — | — | — | 4 | 19.5 | 298 |
| Example 1 | | | | | | | |
| (SC1AJ, | | | | | | | |
| Sinmat) | | | | | | | |
| Comparative | 100 nm silica | KMnO₄ | — | — | 4 | 9.09 | 254 |
| Example 2 | 5 wt % | 0.3M | | | | | |
| Comparative | 100 nm silica | KMnO₄ | Mn³⁺ | — | 4 | 20.22 | 425 |
| Example 3 | 5 wt % | 0.3M | | | | | |
| Comparative | 100 nm silica | KMnO₄ | Mn³⁺ | — | 9 | 17.78 | 179 |
| Example 4 | 5 wt % | 0.3M | | | | | |
| Example 1 | 100 nm silica | KMnO₄ | Cr³⁺ | — | 2.5 | 18.9 | 484 |
| | 5 wt % | 0.3M | | | | | |
| Example 2 | 100 nm silica | KMnO₄ | Fe³⁺ | — | 4 | 20.02 | 452 |
| | 5 wt % | 0.3M | | | | | |
| Example 3 | 100 nm silica | KMnO₄ | Cr³⁺ + Fe³⁺ | — | 2 | 22.86 | 571 |
| | 5 wt % | 0.3M | | | | | |
| Example 4 | 100 nm silica | KMnO₄ | Fe³⁺ | NaNO₂ | 3 | 27.26 | 460 |
| | 5 wt % | 0.3M | | 0.008M | | | |
| Example 5 | 100 nm silica | KMnO₄ | Fe³⁺ | NaNO₂ | 4.5 | 26.5 | 421 |
| | 5 wt % | 0.3M | | 0.08M | | | |
| Example 6 | 100 nm silica | KMnO₄ | Fe³⁺ | — | 2 | 21.40 | 551 |
| | 5 wt % | | | | | | |

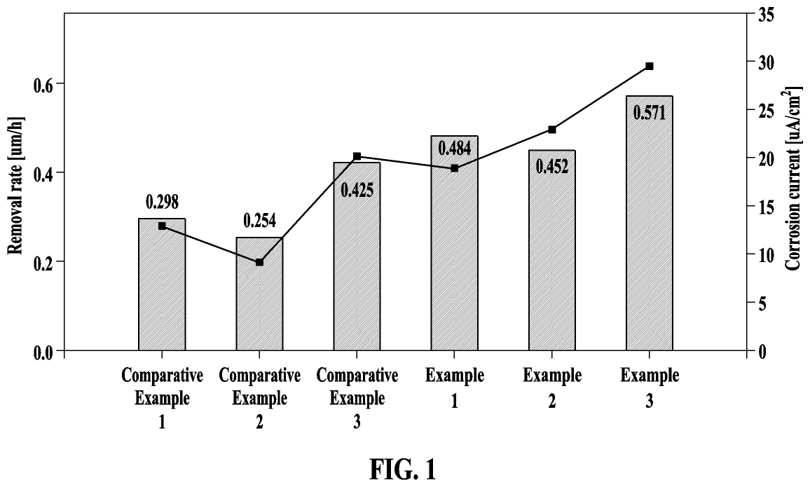

FIG. 1 is a graph showing corrosion currents and removal rates after performing polishing using the polishing slurry compositions of Comparative Examples 1 to 3 of the present disclosure and the polishing slurry compositions for a silicon carbide wafer of Examples 1 to 3.

Referring to FIG. 1, potassium permanganate (KMnO₄) was included as the oxidant to oxidize a surface of the wafer during SiC CMP. MnO₄ ions reacts with SiC to oxidize the wafer while being reduced into a form of MnO₄²⁻ or MnO₂. To further promote the reaction, the transition metal ions are included, which reoxidizes the reduced MnO₄²⁻— or MnO₂ to regenerate it into a form of MnO₄⁻ which may react with SiC. Due to this regeneration reaction, an oxidant capable of reacting with SiC may be re-formed, and at the same time, the formation of undissolved MnO₂, which is adsorbed on the surface of SiC and blocks the reaction site, may be suppressed, thereby further promoting the oxidation reaction on the surface of SiC. It may be confirmed that the corresponding transition metal ions are Fe³⁺, Mn³⁺, and Cr³⁺ ions.

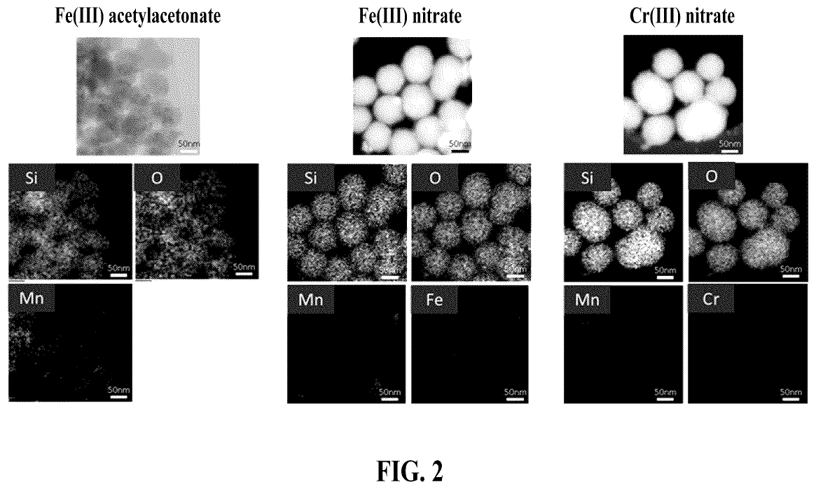

FIG. 2 is an image for confirming whether silica particle surface is coated according to iron (III) acetylacetonate, iron (III) nitrate, and chromium (III) nitrate as transition metal ions.

Referring to FIG. 2, Mn³⁺ ions are precipitated on the surface of the polishing particle in an insoluble form after the reaction, thereby forming a soft layer in a MnOₓ form on the surface of the polishing particle. It may be confirmed that the soft layer on the surface of the polishing particle is not suitable in terms of improving the polishing speed because it reduces the mechanical polishing effect.

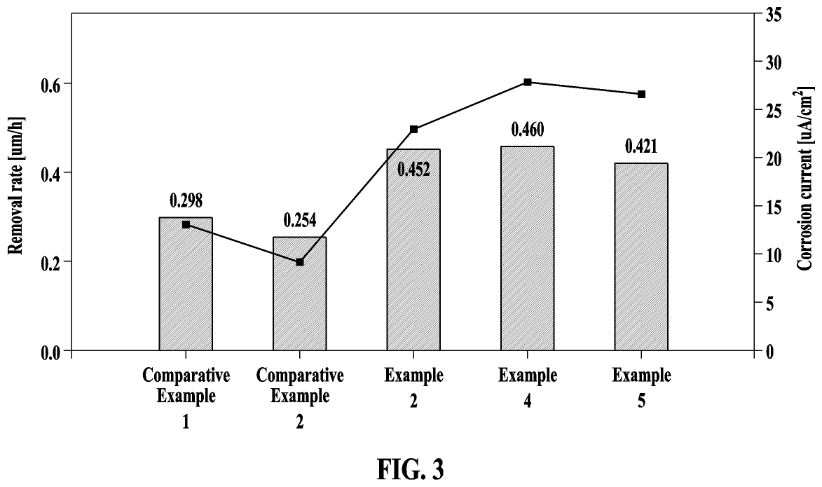

FIG. 3 is a graph showing corrosion currents and removal rates after performing polishing using the polishing slurry compositions of Comparative Examples 1 and 2 of the present disclosure and the polishing slurry compositions for a silicon carbide wafer of Examples 2, 4, and 5.

Referring to FIG. 3, it may be confirmed that the oxidant regeneration reaction of Fe³⁺ ions may be further promoted by a ligand of the transition metal ions. It may be confirmed that, when the transition metal ion complexing agent of NaNO₂⁻ is included, the oxidant regeneration reaction of the transition metal ions may be further promoted, thereby further increasing the polishing speed. At this time, a ratio of the transition metal ion complexing agent to the transition metal ions is most effective when a molar ratio thereof is 1:1, and when more amounts of them are added, it may be confirmed that the transition metal ion complexing agent is precipitated to form a soft layer on the polishing particles, which may lower the polishing speed.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and equivalents to the claims are also within the scope of the following claims.

1. A polishing slurry composition for a silicon carbide wafer, comprising:
polishing particles;
an oxidant;
in a water-soluble transition metal; and
a transition metal ion complexing agent.

2. The polishing slurry composition of claim 1, wherein the polishing particles have a Mohs hardness lower than a Mohs hardness of silicon carbide.

3. The polishing slurry composition of claim 1, wherein
the polishing particles comprise at least one selected from the group consisting of metal oxide, metal oxide coated with an organic or inorganic substance, and the metal oxide in a colloidal state, and
the metal oxide comprises at least one selected from the group consisting of silica, ceria, zirconia, alumina, titania, barium titania, germania, mangania, and magnesia.

4. The polishing slurry composition of claim 1, wherein the polishing particles comprise primary particles having a particle size of 30 nanometers (nm) to 100 nm and secondary particles having a particle size of 250 nm to 300 nm.

5. The polishing slurry composition of claim 1, wherein the polishing particles are in an amount of 0.1 wt % to 10 wt % in the polishing slurry composition for the silicon carbide wafer.

6. The polishing slurry composition of claim 1, wherein the oxidant comprises at least one selected from the group consisting of potassium permanganate (KMnO₄), potassium ferricyanide, potassium dichromate, potassium iodate, potassium bromate, potassium hypochlorite, sodium permanganate (NaMnO₄), sodium hypochlorite (NaClO), sodium bromate (NaBrO₃), hydrogen peroxide, ammonium persulfate, silver nitrate, ferric nitrates, ferric chloride, per acid, per salts, ozone water, vanadium trioxide, hypochlorous acid, sodium hypochlorite, calcium hypochlorite, magnesium hypochlorite, and ferric nitrate.

7. The polishing slurry composition of claim 1, wherein the oxidant is included in an amount of 0.1 M to 5 M in the polishing slurry composition for the silicon carbide wafer.

8. The polishing slurry composition of claim 1, wherein the water-soluble transition metal comprises chromium (Cr) ions, iron (Fe) ions, or both.

9. The polishing slurry composition of claim 8, wherein the chromium (Cr) ions are provided from an iron compound comprising at least one selected from the group consisting of chromium (III) sulfate, chromium (III) chloride, chromium (III) nitrate, and chromium (III) acetate.

10. The polishing slurry composition of claim 8, wherein the iron (Fe) ions are provided from an iron compound comprising at least one selected from the group consisting of iron (III) nitrate, iron (III) sulfate, iron (III) formate, iron (III) acetate, iron (III) carbonate, iron (III) chloride, iron (III) bromide, iron (III) oxalate, iron (III) hydroxide, iron (III) oxide, iron (III) acetylacetone, iron (III) carbon monoxide, iron (III) citrate, iron (III) oxalate, iron (III) fumarate, iron (III) lactate, iron (III) perchlorate, ammonium hexacyanoferrate (III) acid, potassium hexacyanoferrate (III) acid, ammonium iron (III) sulfate, and potassium iron (III) sulfate.

11. The polishing slurry composition of claim 1, wherein the water-soluble transition metal is included in an amount of 0.0001 M to 0.1 M in the polishing slurry composition for the silicon carbide wafer.

12. The polishing slurry composition of claim 1, wherein the transition metal ion complexing agent comprises ions of at least one selected from the group consisting of NO₂⁻, CN⁻, and C₅H₇O₂⁻ (acetylacetonate).

13. The polishing slurry composition of claim 1, wherein the transition metal ion complexing agent comprises at least one selected from the group consisting of NaNO₂, NaCN, NaAcc, KNO₂, KCN, and HNO₂.

14. The polishing slurry composition of claim 1, wherein a molar ratio of the water-soluble transition metal to the transition metal ion complexing agent is 1:0.5 to 1:5.

15. The polishing slurry composition of claim 1, further comprising:
a surfactant,
wherein the surfactant comprises at least one selected from the group consisting of dodecylbenzenesulfonic acid, octylbenzenesulfonic acid, decylbenzenesulfonic acid, dodecanesulfonic acid, tetradecylbenzenesulfonic acid, alkylbenzenesulfonic acid, alkyldiphenyletherdisulfonic acid, polystyrenesulfonate, polysodium styrenesulfonate, sodium dodecylsulfonate, dodecylbenzenesulfonate, n-dodecylpyridinium chloride, linear diamine, linear alkylamine, cetyltrimethylammonium bromide, benzalkonium chloride, benzethonium chloride, cetrimonium chloride, alkyltrimethylammonium chloride, dialkyldimethylammonium chloride, imidazole, glyceride sulfate, dodecylbenzene sulfonate, sodium dodecyl sulfonate, ligrosulfonate, sarcoside, a sulfo-carboxyl compound, alkyl ether sulfate, alkyl sulfate, alpha-olefin sulfonate, an organophosphate-based surfactant, potassium cocoyl glycinate, sulfate alkanolamide, Brij 35, Brij 58, Brij L23, Brij O20, sorbitan monolaurate, sorbitan monostearate, sorbitan tristearate, octaethylene glycol monododecyl ether, pentaethylene glycol monododecyl ether, nonoxynols, Triton X-100, Tween 80, sodium dodecyl sulfate (SDS), sodium deoxycholate, and Triton X-200.

16. The polishing slurry composition of claim 15, wherein the surfactant is included in an amount of 0.2 mM to 5 mM in the polishing slurry composition for the silicon carbide wafer.

17. The polishing slurry composition of claim 1, wherein the polishing slurry composition for the silicon carbide wafer has a pH of 2 to 5.

18. The polishing slurry composition of claim 1, wherein, when polishing a silicon carbide wafer using the polishing slurry composition for the silicon carbide wafer, a removal rate of a silicon carbide film is 400 nm/h to 1,000 nm/h.

19. The polishing slurry composition of claim 1, wherein, when polishing a silicon carbide wafer using the polishing slurry composition for the silicon carbide wafer,
a silicon oxide film (SiO₂) is formed on the silicon carbide surface by the oxidant, and
the polishing particles polish the silicon oxide film (SiO₂).
